(19) United States
(12) Patent Application Publication
(10) Pub. No.: US 2006/0144696 A1
(43) Pub. Date: Jul. 6, 2006

(54) MAGNETRON SPUTTERING PROCESS

(76) Inventors: Yu-Chou Lee, Taipei (TW); Hsiang-Hsien Chung, Taoyuan County (TW); Hung-I Hsu, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,304

(22) Filed: May 6, 2005

(30) Foreign Application Priority Data
Jan. 6, 2005 (TW) 94100337

(51) Int. Cl. C23C 14/32; C23C 14/00

(52) U.S. Cl. 204/192.15; 204/192.1

(57) ABSTRACT

A magnetron sputtering process is provided. First, a reaction chamber including a substrate base, a target comprised of Al or its alloy or other metals or their alloy with higher melting point, and a magnetron device. Next, a substrate is disposed onto the substrate base. The pressure within the reaction chamber is set from 0.1 pa˜0.35 pa, and then a sputtering process is initiated within the reaction chamber to deposit a film on the substrate. Because the pressure within the reaction chamber is set from 0.1 pa˜0.35 pa, a better step coverage can be achieved during the sputtering process so that a continuous film can be deposited on the substrate without the broken or defective climbing portion of the film. Therefore, the yield of film deposition on the substrate can also be significantly increased.

### CROSS-REFERENCE TO RELATED APPLICATION

This application claims the priority benefit of Taiwan application serial no. 94100337, filed on Jan. 6, 2005. All disclosure of the Taiwan application is incorporated herein by reference.

### BACKGROUND OF THE INVENTION

1. Field of the Invention

The present invention relates to a sputtering process. More particularly, the present invention relates to a magnetron sputtering process capable of improving the film quality and promoting the yield rate of film deposition on a substrate.

2. Description of Related Art

Generally, the deposition processes for depositing a film on a substrate in semiconductor fields or flat panel display (FPD) fields can be broadly divided into two categories, i.e. physical vapor deposition (PVD) and chemical vapor deposition (CVD). In the physical vapor deposition category, the often-used deposition process is the sputtering process. The principle of the sputtering process include subjecting gas ions to an electrical field for impinging the ions onto a metal target, consequently secondary electrons and atoms of the metal target are produced during the ion bombardment process.

Next, the electrons gather enough energy to bombard gas molecules within the chamber to produce an abundant amount of ions, atoms, radicals and electrons, i.e. so called plasma, by way of dissociation, ionization and excitation reaction. Afterwards, these hit-out atoms of the metal target will enter the plasma to deposit onto a surface of an object in a form of a film or layer, and the sputtering process may be continued until a film or layer of desired thickness is obtained.

However, the concentration of the ions and electrons in the chamber must be sustained, in order to keep the aforementioned reactions. However, electrons generated may easily escape from the chamber via the ground. Therefore, how to maintain a desirable concentration of electrons within the chamber has a subject of significant importance. Accordingly, a magnetron sputtering process is being developed for sustaining the concentration of the electrons within the chamber, in order to enhance the bombardment frequency between the electrons and the gas molecules within the chamber. The following illustrates this situation in detail.

FIG. 1 is a perspective schematic view of a reaction chamber utilized in a conventional magnetron sputtering process. Referring to FIG. 1, a conventional magnetron sputtering process is carried out within the reaction chamber to deposit a film on a substrate, wherein the conventional magnetron sputtering process includes the following steps. First, a reaction chamber 100 is provided, wherein the reaction chamber 100 comprises a substrate base 110, a target 120, a magnetron device 130, a gas 140 for the sputtering process, a piping 150, a mass flow controller 160 and a gas-extraction outlet 170. The substrate base 110 and the target 120 are located within two sides of the reaction chamber 100 respectively. The magnetron device 130 is disposed outside the reaction chamber 100 and adjacent to the target 120, wherein the types of the magnetron device 130 can be fixed type or removable type. All electrons in the reaction chamber 100 will be affected by the magnetron device 130 to move along a spiral path. The collision possibility between the gas molecules and the electrons within the reaction chamber 100 can be increased by extending the motion path of the electrons within the reaction chamber 100. So the plasma density in the reaction chamber 100 will be increased to facilitate the deposition rate of the sputtering process.

Referring to FIG. 1, the gas required for the sputtering process is inputted into the reaction chamber 100 by the piping 150 and the mass flow controller 160. For example, the gas-extraction outlet 170 is connected with a vacuum pump (not shown). The gas within the reaction chamber 100 can be extracted outside by the vacuum pump to lower the pressure with the reaction chamber 100 to meet the vacuum level required during the sputtering process.

Next, a substrate 10 is fixed on the substrate base 110 within the reaction chamber 100. During the sputter process, the pressure within the reaction chamber 100 is maintained around 1 pa (pascal). It should be noted that despite the deposition rate can be increased significantly by utilizing the magnetron device, however there are several disadvantages described as follows. After the film on the substrate 10 is patterned by a patterning process, some blind holes or exposed holes are formed on the side wall of the film pattern because of the poor step coverage of the film, especially when the target is made of high melting point material, i.e. Cr, Mo, W, Ti, Ta and alloy thereof. This condition will be illustrated as followings.

FIG. 2 is a perspective schematic view of a film deposited on a surface of the substrate using a conventional magnetron sputtering process. Referring to FIG. 2, the sidewalls (i.e. generally called climbing portion) of the patterned film 12 may be cracked easily or at least one blind hole 16 may be formed therein after being patterned in the conventional magnetron sputtering process (so called the broken or defective climbing portion of the patterned film). The broken or defective climbing portion of the patterned film will result in the open circuit to lower the yield rate of film deposition.

### SUMMARY OF THE INVENTION

Accordingly, the present invention is directed to a magnetron sputtering process capable of improving the open circuit resulted from the broken or defective climbing portion of the patterned film to promote the yield rate of film deposition on a substrate.

According to an embodiment of the present invention, a magnetron sputtering process is disclosed. The magnetron sputtering process includes the following steps. First, a reaction chamber is provided. The reaction chamber comprises a substrate base, a target and a magnetron device. Next, a substrate is disposed on the substrate base. Thereafter, the pressure is set from 0.1 pa˜0.35 pa within the reaction chamber and a suitable plasma is generated to carry out the deposition of a film on the substrate.

According to an embodiment of the present invention, during the sputtering process, the power of the direct-current is set from 25 KW˜55 KW and the substrate is heated from 25° C.˜22° C.

According to an embodiment of the present invention, the target comprises a metal such as Al, Al alloy, other metals having melting points larger than Al or Al alloy, wherein the metals include Cr, Mo, W, Ti or Ta and an alloy thereof.

According to an embodiment of the present invention, because the pressure within the reaction chamber during the magnetron sputtering process of the present invention is set from 0.1 pa˜0.35 pa, the yield rate of film deposition on the substrate is significantly enhanced, especially when the deposition film is made of materials with higher melting point compared to that of Al. In addition to the pressure within the reaction chamber being set from 0.1 pa˜0.35 pa, the power of the direct-current is set from 25 KW˜55 KW and the substrate is heated and maintained at a temperature from 25° C.˜22° C. during the sputtering process, so as to further increase the yield rate of film deposition on substrate.

### BRIEF DESCRIPTION OF THE DRAWINGS

FIG. 1 is a perspective schematic view of a reaction chamber utilized in a conventional magnetron sputtering process.

FIG. 2 is a perspective schematic view of a film deposited on a substrate utilizing a conventional magnetron sputtering process.

FIG. 3A is a perspective schematic view of a reaction chamber utilized in a magnetron sputtering process according to one embodiment of the present invention.

FIG. 3B is a top view of the magnetron device shown in FIG. 3A.

FIG. 4 is a perspective schematic view of a film deposited on the patterned film on a substrate utilizing a magnetron sputtering process according to one embodiment of the present invention.

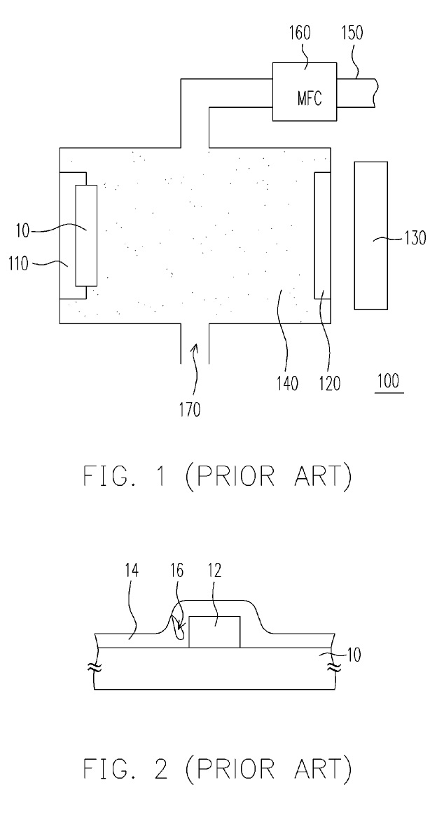

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

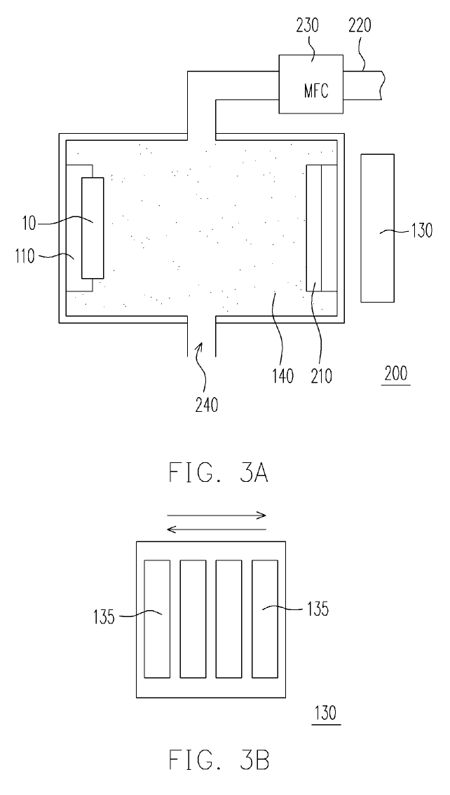

FIG. 3A is a schematic view of a reaction chamber utilized in a magnetron sputtering process according to one embodiment of the present invention. Referring to FIG. 3A, the magnetron sputtering process of the present invention comprises the following steps. First, a reaction chamber 200 is provided, wherein the reaction chamber 200 comprises at least a substrate base 110, a target 210, a magnetron device 130 and a gas 140 for sputtering process. The target 210 comprises Al, Al alloy, other metals such as Cr, Mo, W, Ti, Ta or alloy thereof, wherein the metals have higher melting points compared to that of Al or Al alloy. The substrate base 110 is adapted for fixing a substrate 10 within the reaction chamber 200 and for heating the substrate 10.

Referring to FIG. 3A, the substrate base 110 and the target 210 are discretely disposed within the reaction chamber 200, wherein the substrate base 110 and the target 210 can serve as a electrodes respectively where an electric power is supplied thereto to generate an electrical field within the reaction chamber 200, for example, the substrate base 110 is an anode and the target 210 is a cathode. As a result an abundant amount of cations of the plasma 140 within the reaction chamber 200 will bombard the target 210 along a direction of the electrical field to initiate a sputtering process.

Referring to FIG. 3A, the magnetron device 130 is located outside the reaction chamber 200 and is positioned adjacent to the target 210. FIG. 3B is a top view of the magnetron device shown in FIG. 3A. Referring to FIGS. 3A and 3B, the magnetron device 130 includes one or a plurality of magnets 135 and a device (not shown), wherein the moving device is adapted to move these magnets 135 (if the type of the magnetron device 130 is the movable type). The magnetic field generated by the magnetron device 130 enables the electrons to move along a spiral path within the reaction chamber 200 so that the bombardment between these electrons and the gas molecules within the reaction chamber 200 can be effectively increased. Consequently, both the plasma density and the deposition rate can also be effectively increased within the reaction chamber 200.

Furthermore, the reaction chamber 200 further includes a piping 220, a mass flow controller (MFC) 230 and a gas-extraction outlet 240, wherein the required gas can be supplied into the reaction chamber 200 through the mass flow controller 230 (which is utilized for controlling the gas flow) and the piping 220. The gas-extraction outlet 240 is, for example, connected with a vacuum pump (not shown). By operating the vacuum pump, the gas within the reaction chamber 200 can be pumped out of the reaction chamber 200, so as to lower the pressure within the reaction chamber 200 to keep the required vacuum level during the sputtering process.

Next, a substrate 10 is fixed onto the substrate base 110 within the reaction chamber 200. The pressure of the reaction chamber 200 is set from 0.1 pa˜0.35 pa by operating the vacuum pump and the mass flow controller 230. The gas 140 for sputtering process, for example, including a noble gas such as Ar or He, is then supplied into the reaction chamber 200. Noticeably, a better step coverage during metal film deposition is achieved when the pressure is set from 0.1 pa˜0.35 pa within the reaction chamber 200. It should be noted that it is possible to achieve even a better step coverage during the deposition of higher melting-point (compared to the melting-point than Al or Al alloy) metal film such as Cr, Mo, W, Ti, Ta or an alloy thereof at a pressure from 0.1 pa˜0.35 pa within the reaction chamber 200. Therefore, even when the film or layer deposited on the surface of the substrate 10 obtained by the sputtering process of the present invention is subjected to a patterning process, the possibility of formation of blind holes or cracking on the side wall of the patterned film or layer can be substantially reduced.

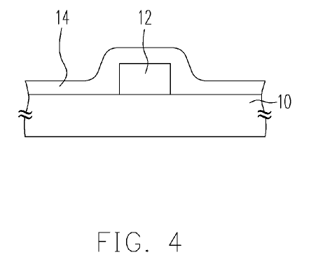

FIG. 4 is a perspective schematic view of a film deposited on the patterned film over a substrate utilizing a magnetron sputtering process according to one embodiment of the present invention. Referring to FIG. 4, the patterned film 12 formed via a patterning process is shown to have protruded structures protruding over the surface of the substrate 10, wherein the substrate 10 shown in FIG. 4 comprises a glass silicon substrate, the bottom layer of the patterned film 12 or other films. Because the pressure is set from 0.1 pa˜0.35 pa within the reaction chamber 200 during the magnetron sputtering process of the present invention, the substrate 10 and the patterned film 12 will be completely covered with the continuous film 14. So that not only a better step coverage is achieved to reduce the broken or defective climbing portion of the patterned film but also the yield rate of film deposition on the substrate 10 can be effectively promoted.

Besides setting the pressure from 0.1 pa˜0.35 pa within the reaction chamber during the magnetron sputtering process, by adjusting other process conditions, such as (1) setting a power of the sputtering process about from 25 KW˜55 KW; (2) heating and maintaining the substrate 10 from 25° C.˜22° C. (room temperature), the process performance can be further promoted.

Table 1 illustrates the effect of the magnetron sputtering process of the present invention obtained from some experimental data.

TABLE 1

| | Temperature of | Electric | | The numbers of the |
|---|---|---|---|---|
| | the substrate | power | Pressure | broken or defective |
| | (° C.) | (KW) | (Pa) | climbing portion |
| Reference | 180 | 25 | 0.35 | 7 |
| example 1 | | | | |
| Example 2 | 180 | 25 | 0.2 | 0 |
| Example 3 | 180 | 25 | 0.25 | 0 |
| Example 4 | 180 | 25 | 0.33 | 0 |
| Reference | 180 | 55 | 0.2 | 1 |
| example 2 | | | | |

As can be seen from the data on Table 1 above, in the examples 2, 3 and 4 where (1) the temperature of the substrate is set at 180oC; (2) the power of the sputtering process is set at 25 KW; (3) the pressure is maintained at 0.2 pa, 0.25 pa and 0.33 pa, the numbers of the broken or defective climbing portion of the patterned film are obtained 0 respectively. On the other hand, in the example 1 where the pressure is set at 0.35 pa within the reaction chamber while the other process conditions are identical to examples 2, 3 and 4, the number of the broken or defective climbing portion of the patterned film is 7. In addition, while the pressure is set at 0.1 pa within the reaction chamber 200, the stability of the plasma gas is higher. To sum up, the pressure is set from 0.1 pa˜0.35 pa during the magnetron sputtering process of the present invention.

Additionally, in the reference example 2 where the power set at 55 KW within the reaction chamber, the number of the broken or defective climbing portion of the patterned film is 1 while the other process conditions are identical to example 2 (Although the pressures are all set from 0.1 pa˜0.35 pa in the reference example 2 and the example 2). Therefore, compared to the number of the broken or defective climbing portion “0” in example 2, the yield rate of the magnetron sputtering process in the reference example 2 is lower.

Moreover, theoretically, the step coverage of the film will be enhanced due to the promotion of the mobility of atoms with higher temperature. However, when the temperature is too high (i.e. over 220° C. proved by experiment), the silicon will combine with the metal film deposited thereon to produce a silicon metal oxide which is adverse to the subsequent sputtering process. To sum up, the temperature is set from 25° C.˜22° C. (room temperature) during the magnetron sputtering process of the present invention.

In conclusion, by setting a pressure from 0.1 pa˜0.35 pa within the reaction chamber in a magnetron sputtering process of the present invention, it is possible to form a more complete and continuous film or layer on the surface of the substrate according to an embodiment of the present invention, so that not only a good step coverage is achieved but also the yield rate of film deposition on the substrate can be significantly promoted.

It should be noted that the sputtering process of the present invention suitable for depositing Al or Al alloy film with desirables features described above, but also suitable for depositing other higher melting point metals and an alloy thereof (compared to the melting point of Al or Al alloy) where the desirable features described above would be even more pronounced than that achieved with Al or Al alloy film. Therefore, the sputtering process of the present invention can be favorably applied for depositing a variety of metal films, and therefore the throughput of the machine can be effectively increased.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A magnetron sputtering process, comprising:
providing a reaction chamber, wherein the reaction chamber comprises at least a substrate base, a target and a magnetron device;
fixing a substrate on the substrate base;
setting a pressure from 0.1 pa˜0.35 pa within the reaction chamber; and
initiating a sputtering process to deposit a film on the substrate.

2. The magnetron sputtering process of claim 1, wherein the power of the sputtering process is from 25 KW˜55 KW.

3. The magnetron sputtering process of claim 1, wherein the substrate is heated from 25° C.˜22° C.

4. The magnetron sputtering process of claim 1, wherein the target comprises a metal.

5. The magnetron sputtering process of claim 4, wherein the metal comprises Al or Al alloy.

6. The magnetron sputtering process of claim 4, wherein the metal has a melting point higher than that of Al or Al alloy.

7. The magnetron sputtering process of claim 6, wherein the metal comprises Cr, Mo, W, Ti or Ta and an alloy thereof.
